(19) United States
(12) Patent Application Publication
(10) Pub. No.: US 2004/0051159 A1
(43) Pub. Date: Mar. 18, 2004

(54) Semiconductor device and semiconductor device manufacturing method

(75) Inventor: Koichi Terashima, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION

(21) Appl. No.: 10/644,812

(22) Filed: Aug. 21, 2003

(30) Foreign Application Priority Data
Aug. 29, 2002 (JP) 249985/2002

(51) Int. Cl. H01L 29/00

(52) U.S. Cl. 257/506

(57) ABSTRACT

A semiconductor substrate is provided including an isolation region buried insulating material in a trench formed in the semiconductor substrate, a plurality of films in at least one part of a bounded area between the semiconductor substrate and the isolation region, wherein the plurality of films comprises a silicon thin film and a silicon oxide film or a silicon oxynitridefilm, and the silicon thin film is nearer to the substrate than the silicon oxide film or the silicon oxynitridefilm.

### BACKGROUND OF THE INVENTION

1. Field of the Invention

The present invention relates to a semiconductor device and semiconductor device manufacturing method, and more particularly, to a semiconductor device in which an isolation structure is formed in a semiconductor substrate and its manufacturing method.

2. Description of the Related Art

Conventionally, manufacturing a semiconductor device such as a MOS transistor includes forming an isolation region to electrically isolate an individual element. For a method of forming the isolation region, technique for forming a groove called a trench in a semiconductor substrate and burying an insulating film such as a silicon oxide film in the groove is known. The isolation technique for burying the insulating film in the trench is advantageous in the miniaturization of a transistor and is currently widely used.

FIGS. 1(a) through (d) show a process for producing an isolation region for burying an insulating film in a trench. First, as shown in FIG. 1(a), on a silicon substrate 53 a pad oxide film 52A made of a silicon oxide film is formed and a mask nitride film 52B made of a silicon nitride film is formed on the pad oxide film 52A. Next, an opening is provided to the pad oxide film 52A and the mask nitride film 52B respectively in a region in which a trench is to be formed using photolithography and etching technique. As shown in FIG. 1(b), a dry etching is performed using the mask nitride film 52B as a mask and a trench 55 is formed in the silicon substrate 53. Then, a silicon thermal oxide film 59 is formed at the bottom and on the side of the trench 55. Next, as shown in FIG. 1(c), an insulating film for isolating an element 57 made of a silicon oxide film is deposited using chemical vapor deposition (CVD) and the insulating film for isolating an element 57 is buried in the trench. Next, as shown in FIG. 1(d), the extra insulating film for isolating an element 57 over the trench, the mask nitride film 52B, and the pad oxide film 52A respectively above the trench are removed by chemical-mechanical polishing (CMP) and etching.

Further, in the isolation technique utilizing such a trench, a method of preventing a crystal defect and the deterioration by stress of the characteristic of a device is disclosed in Japanese published application 2001-267413A and 2002-110780A for example. In either case, before an insulating film such as a silicon oxide film is buried in a trench, a silicon thermal oxide film is formed at the bottom and on the side of the trench to prevent a defect and an interface state between the insulating film and the substrate from being caused.

On the other hand, recently, to enhance the performance of a MOS transistor by increasing the mobility of a carrier, a MOS transistor using a silicon-germanium mixed crystal layer and a strained silicon layer on a silicon-germanium mixed crystal layer for a channel has been proposed. For example, in IEEE Transactions on Electron Devices, Vol. 48, No. 8, 1612-1618, 2001, a strained silicon channel MOS transistor using a strained silicon layer formed on a silicon-germanium mixed crystal layer for a channel is reported. According to the technique, the larger mobility of a hole is acquired than that of a p-MOS transistor formed on a normal silicon substrate, by forming a p-MOS transistor on a substrate having the thin strained silicon layer laminated on the silicon-germanium mixed crystal layer the strain of which is relieved.

Furthermore, techniques for forming a transistor on a substrate having a silicon-germanium mixed crystal layer such as a MOS transistor using the similar strained silicon layer for a channel and a MOS transistor using a silicon-germanium mixed crystal layer for a channel is disclosed in Japanese patent publications No. 2994227B and No. 3221901B for example.

However, in case the strained silicon channel MOS transistor is formed on the substrate having a silicon-germanium mixed crystal layer, the following problems are caused in the isolation method of burying the insulating film in the trench for isolation region.

First, in a thermal oxidation process after the trench is formed, the silicon-germanium mixed crystal layer is thermally oxidized. The thermal oxidation process after the trench is formed is a process which cannot be omitted to prevent a defect and an interface state between the insulating film for burying in the trench and the substrate from being caused as described above. When the silicon-germanium mixed crystal layer is thermally oxidized, germanium piles up at on an interface between an oxide film and the substrate because a germanium atom is swept out from the formed oxide film. The piling up of germanium causes the recombination of an electron and a hole and causes a defect such as dislocation. As a result, a leakage current in the transistor increases and the electrical insulation performance of the isolation region is deteriorated.

Second, as silicon and silicon-germanium are different in oxidizing velocity, the oxide film on the silicon-germanium mixed crystal layer is thicker than an oxide film on a silicon layer when the silicon layer exists on the silicon-germanium mixed crystal layer and the structure is thermally oxidized. Therefore, the shape of the trench in the isolation region becomes abnormal. As stress concentration is caused in the unusual shaped part, a defect occurs and leakage current increases.

### SUMMARY OF THE INVENTION

An object of the present invention is to provide a semiconductor device provided with the isolation structure having high isolation performance. More particularly, the present invention provides a semiconductor device wherein the damage by thermal oxidation of silicon substrate and the abnormality of the shape of the trench are prevented when the isolation structure by a trench is formed in a substrate, and as a result, deterioration of the characteristics of a transistor is decreased.

According to a first aspect of the present invention, a semiconductor device comprises a semiconductor substrate, at least one isolation region buried insulating material in a trench formed in the semiconductor substrate, a plurality of films in at least one part of a bounded area between the semiconductor substrate and the isolation region, wherein the plurality of films comprises a silicon thin film and a silicon oxide film or a silicon oxynitride film, and the silicon thin film is nearer to the substrate than the silicon oxide film or the silicon oxynitride film.

Thus, according to the present invention, it is possible to acquire further high element isolation performance as the silicon layer having a larger band gap exists between the insulating film for isolating an element and the semiconductor layer.

According to a second aspect of the present invention, a semiconductor device comprises a semiconductor substrate, at least one isolation region buried insulating material in a trench formed in the semiconductor substrate, a plurality of films in at least one part of a bounded area between the semiconductor substrate and the isolation region, wherein the plurality of films comprises a silicon thin film and a silicon oxide film or a silicon oxynitride film, and the silicon thin film is nearer to the substrate than the silicon oxide film or the silicon oxynitride film, further comprises at least one germanium thin film layer or one semiconductor thin film layer including germanium in at least the vicinity of the isolation region from the surface of the semiconductor substrate to the bottom of the trench.

Thus, according to the present invention, as in the process for manufacturing the isolation structure in the substrate including germanium as a component, the silicon thin film is epitaxially grown on the side and at the bottom of the trench after the trench is formed, is partially thermally oxidized in the direction of the thickness and the silicon thermal oxide film is formed, the semiconductor layer including germanium as a component and the other layers forming the substrate are not oxidized. Hereby, the piling up of germanium and the abnormality of the shape of the trench can be prevented from being caused at the interface between the silicon thermal oxide film and the silicon thin film and between the silicon thin film and the semiconductor layer including germanium as a component.

According to a third aspect of the present invention, a method of manufacturing a semiconductor device comprises forming at least one trench on a semiconductor substrate, epitaxially growing a silicon thin film at the bottom and on the side of the trench, partially thermally oxidizing or partially thermally oxynitriding the silicon thin film in a direction of the thickness in an oxidizing atmosphere or in an oxynitriding atmosphere and forming a silicon oxide film or a silicon oxynitride film on said silicon thin film, and burying an insulating film for isolating an element in a residual trench.

Thus, according to the present invention, as in the process for manufacturing the isolation structure in the substrate including germanium as a component, the silicon thin film is epitaxially grown on the side and at the bottom of the trench after the trench is formed, is partially thermally oxidized in the direction of the thickness and the silicon thermal oxide film is formed, the semiconductor layer including germanium as a component and the other layers forming the substrate are not oxidized. Hereby, the piling up of germanium and the abnormality of the shape of the trench can be prevented from being caused at the interface between the silicon thermal oxide film and the silicon thin film and between the silicon thin film and the semiconductor layer including germanium as a component.

### BRIEF DESCRIPTION OF THE DRAWINGS

FIGS. 1(a) through (d) are the sectional views in the order of processes for explaining a conventional type method of manufacturing element isolation structure.

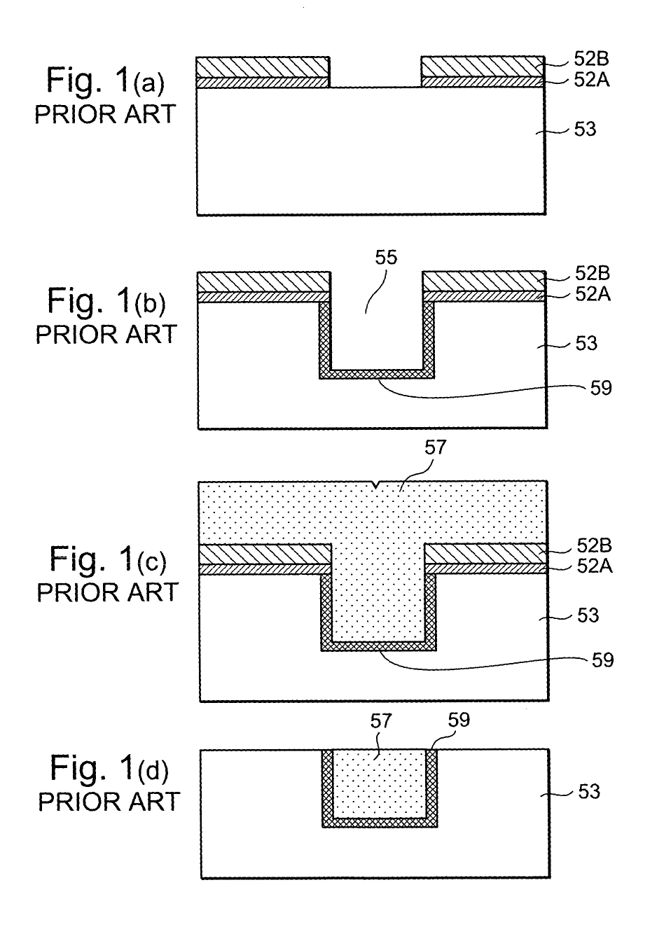

FIGS. 2(a) through (c) are sectional views in the order of processes for explaining a method of manufacturing isolation structure of a semiconductor device to a first embodiment of the invention.

FIGS. 3(a) through (c) are sectional views showing processes succeeding the processes shown in FIGS. 2 in the order of processes for the method of manufacturing the isolation structure of the semiconductor device to the first embodiment of the invention;

FIG. 4 is a sectional view showing element isolation structure of a semiconductor device to a second embodiment of the invention.

FIGS. 5(a) through (c) are a part of sectional views in the order of processes for a method of manufacturing isolation structure of a semiconductor device to a third embodiment of the invention.

FIGS. 6(a) and (b) are sectional views showing processes succeeding the processes shown in FIGS. 5 in the order of processes for the method of manufacturing the element isolation structure of the semiconductor device to the third embodiment of the invention.

FIGS. 7(a) through (c) are a part of sectional views in the order of processes for a method of manufacturing isolation structure of a semiconductor device to a fourth embodiment of the invention.

FIGS. 8(a) and (b) are sectional views showing processes succeeding the processes shown in FIGS. 7 in the order of processes for the method of manufacturing the isolation structure of the semiconductor device to the fourth embodiment of the invention.

### DETAILED DESCRIPTION OF THE INVENTION

### First Embodiment

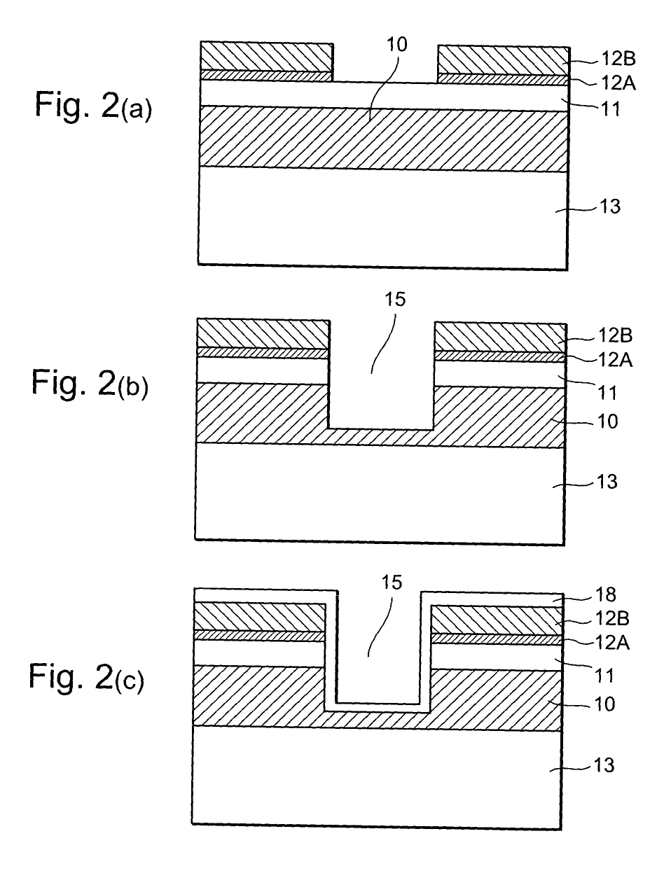

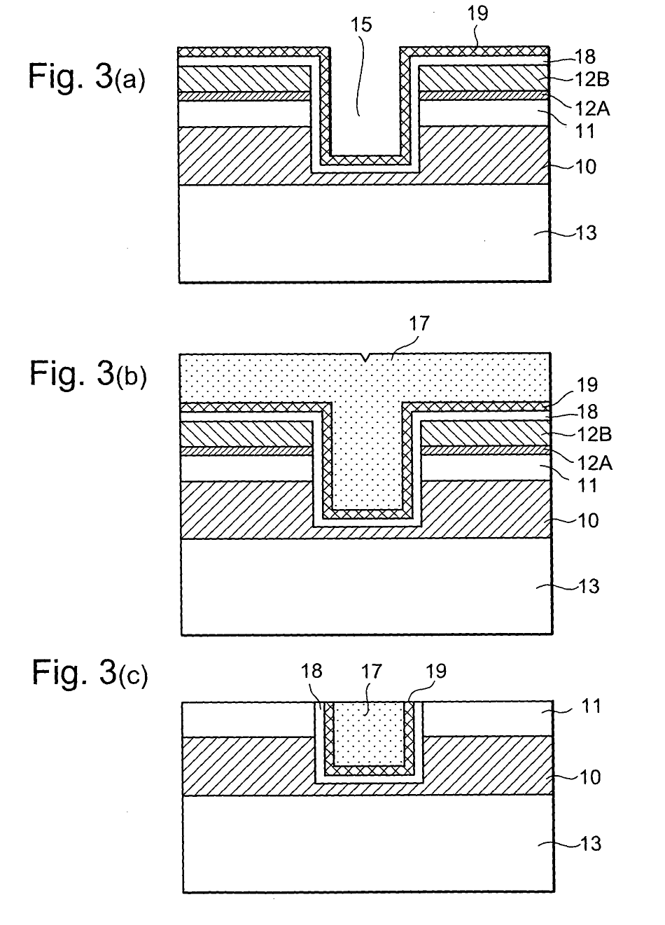

FIGS. 2 and 3 are sectional views in the order of processes for explaining a method of manufacturing an isolation structure in a semiconductor device according to a first embodiment of the invention. A silicon-germanium mixed crystal layer 10 and a silicon thin film layer 11 are grown on a silicon substrate 13 by molecular beam epitaxial growth (MBE) or CVD. The strain of the silicon-germanium mixed crystal layer 10 is relieved and the silicon thin film layer 11 is strained by lattice matching with the silicon-germanium mixed crystal layer 10. The isolation structure is formed on a semiconductor substrate comprising the silicon substrate 13, the silicon-germanium mixed crystal layer 10 and the silicon thin film layer 11.

First, as shown in FIG. 2(a), a pad oxide film 12A made of a silicon oxide film is formed on the silicon thin film layer and a mask nitride film 12B made of a silicon nitride film is formed on the pad oxide film 12A. The pad oxide film 12A and the mask nitride film 12B can be formed by a normal film formation process such as sputtering and CVD, however, the pad oxide film 12A is often formed particularly by thermal oxidation. Then an opening having a pattern of a trench is provided to the pad oxide film 12A and the mask nitride film 12B in a region in which the trench is formed using photolithography and etching technique. Next, as shown in FIG. 2(b), dry etching is performed using the mask nitride film 12B as a mask and a trench 15 that reaches the inside of the silicon-germanium mixed crystal layer 10 is formed. In FIG. 2(c), the side of the trench 15 is perpendicular to the main surface of the substrate, however, the side of the trench 15 may be also inclined at a certain angle which is not right-angled with the main surface of the substrate by varying a condition of dry etching.

Next, as shown in FIG. 2(c), a silicon thin film 18 is epitaxially grown on the surfaces of the silicon-germanium mixed crystal layer 10 and the silicon thin film layer 11 at the bottom and on the side of the trench 15 and is grown on the surface of the mask nitride film 12B so that the silicon thin film is polycrystalline or amorphous. The silicon thin film 18 can be grown by an arbitrary method in which the silicon thin film can be epitaxially grown on silicon germanium and silicon such as MBE and CVD. Before the silicon thin film 18 is grown, damage layer may be removed by wet etching and heat treatment and the surface may be planarized to remove damage caused when the trench 15 is formed.

Next, as shown in FIG. 3(a), a silicon thermal oxide film 19 is formed on the surface of the silicon thin film 18 by heating in an oxidizing atmosphere. At this time, thermal oxidation is performed under a condition that the silicon thin film 18 is partially thermally oxidized in a direction of the thickness. Therefore, the silicon-germanium mixed crystal layer 10 and the silicon thin film layer 11 are not oxidized. Hereby, the separation of germanium from the silicon-germanium mixed crystal layer 10 can be prevented. And the abnormality of the shape of the trench caused by difference in an oxidizing velocity between silicon and a silicon-germanium mixed crystal can be prevented. For a thermally oxidizing method, it is preferable to use a thermal oxidation process in which the generation of an interface state is reduced, for example, a wet oxidation process. To prevent the diffusion of impurities and stress concentration, a silicon thermal oxynitride film may be also formed on the surface of the silicon thin film 18 by, for example, heating in an oxynitriding atmosphere in place of the silicon thermal oxide film. In a dry oxidation process, O₂ gas, O₃ gas or their mixed gas can be used and in the wet oxidation process, H₂O gas or H₂O gas-O₂ gas mixed gas can be used. In a thermal oxynitridation process, NO gas, N₂O gas, mixed gas in which they and O₂ gas are mixed and mixed gas in which they and N₂ gas are mixed can be used. In addition, another processes which can form the silicon oxynitride film can be used.

Next, as shown in FIG. 3(b), an insulating film 17 for isolating an element made of a silicon oxide film is deposited by CVD so that it is buried in the trench. Afterward, as shown in FIG. 3(c), the extra insulating film for isolating an element 17 over the trench, the silicon thermal oxide film 19 and the silicon thin film 18 respectively above the trench are removed by CMP. CMP is stopped at a time when the mask nitride film 12B is exposed, and thereafter, the mask nitride film 12B and the pad oxide film 12A are removed by wet etching.

Afterward, a MOS transistor provided with a strained silicon layer as a channel can be formed by a normal method of manufacturing a MOS transistor. In this embodiment, as described above, as piling up of germanium at an interface between the silicon oxide film buried in the trench and the substrate can be prevented and abnormality of the shape of the trench can be prevented, the isolation structure having deterioration of the characteristics of the transistor caused by leakage current can be avoided. In addition, in this embodiment, as the diffusion of carriers in the silicon-germanium mixed crystal layer the band gap of which is small is prevented by the silicon layer the band gap of which is large, higher element isolation performance can be acquired.

In this embodiment, the isolation structure is manufactured in the semiconductor device using the substrate including one silicon-germanium mixed crystal layer and one silicon thin film layer described above, however, the manufacturing method in this embodiment can be applied to a semiconductor device provided with at least one silicon-germanium mixed crystal layer to a substrate. For example, the manufacturing method in this embodiment can be also applied to a MOS transistor using a silicon-germanium mixed crystal layer for a channel which is manufactured using a substrate including the silicon-germanium mixed crystal layer and a semiconductor device using a superlattice in which a silicon-germanium mixed crystal layer and a silicon layer are alternately laminated on a substrate. Furthermore, for a substrate provided with a silicon-germanium mixed crystal layer, a silicon-germanium-on-insulator (SGOI) substrate and a substrate in which a silicon-germanium mixed crystal layer is epitaxially grown on an SOI substrate can be also used. In addition, in place of the silicon-germanium mixed crystal layer, a germanium layer or a silicon-germanium mixed crystal layer into which carbon is doped can also be used. The insulating film for isolating an element buried in the trench is not limited to the silicon oxide film and a substance having insulation performance such as a silicon oxynitride film and a silicon nitride film or the combination of them can be also used.

### Second Embodiment

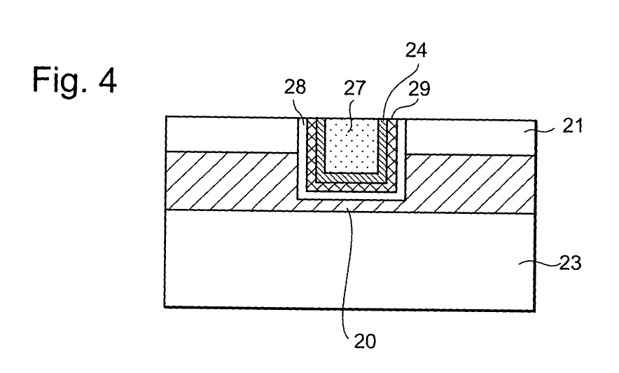

FIG. 4 is a sectional view showing element isolation structure in a semiconductor device according to a second embodiment of the invention. In FIG. 4, a reference number having the same number on the first digit is allocated to the similar part to the part in the first embodiment shown in FIG. 3(c) and the description is omitted. This embodiment is different from the first embodiment shown in FIG. 3(c) in that a silicon nitride film 24 is formed between an insulating film 27 buried in a trench and a silicon thermal oxide film 29.

Element isolation structure in the semiconductor device of this embodiment is manufactured as follows. First, as in the first embodiment shown in FIGS. 2(a) to 3(a), a trench is formed in a semiconductor substrate including a silicon-germanium mixed crystal layer 20 and a silicon thin film layer 21. A silicon thin film 28 is epitaxially grown on the surfaces of the silicon-germanium mixed crystal layer 20 and the silicon thin film layer 21 on the side and at the bottom of the trench. Next, thermal oxidation is performed by partially oxidizing the silicon thin film 28 in a direction of the thickness and a silicon thermal oxide film 29 is formed on the surface of the silicon thin film 28. Next, the silicon nitride film 24 is formed on the surface by CVD, and then the insulating film for isolating an element 27 made of a silicon oxide film is formed so that it is buried in the trench. Afterward, as in the first embodiment, extra films above the upper surface of the silicon layer 21 are removed, and the element isolation structure shown in FIG. 4 is acquired,

In a method of manufacturing the element isolation structure in this embodiment, no germanium is piles up at an interface between the insulating film for isolating an element 27 buried in the trench and the substrate and no abnormality of the shape of the trench is caused, thereby causing a similar effect to that described in the first embodiment. Further, as in the element isolation structure in this embodiment, the silicon nitride film 24 as a cushioning layer exists between the insulating film for isolating an element 27 buried in the trench and the silicon thermal oxide film 29, a synergistic effect that stress on the substrate by the insulating film for isolating an element 27 is reduced, thereby reducing the possibility of defects.

For the insulating film 27 buried in the trench, as in the first embodiment, a silicon oxide film, a silicon oxynitride film, a silicon nitride film or the combination thereof can be used.

### Third Embodiment

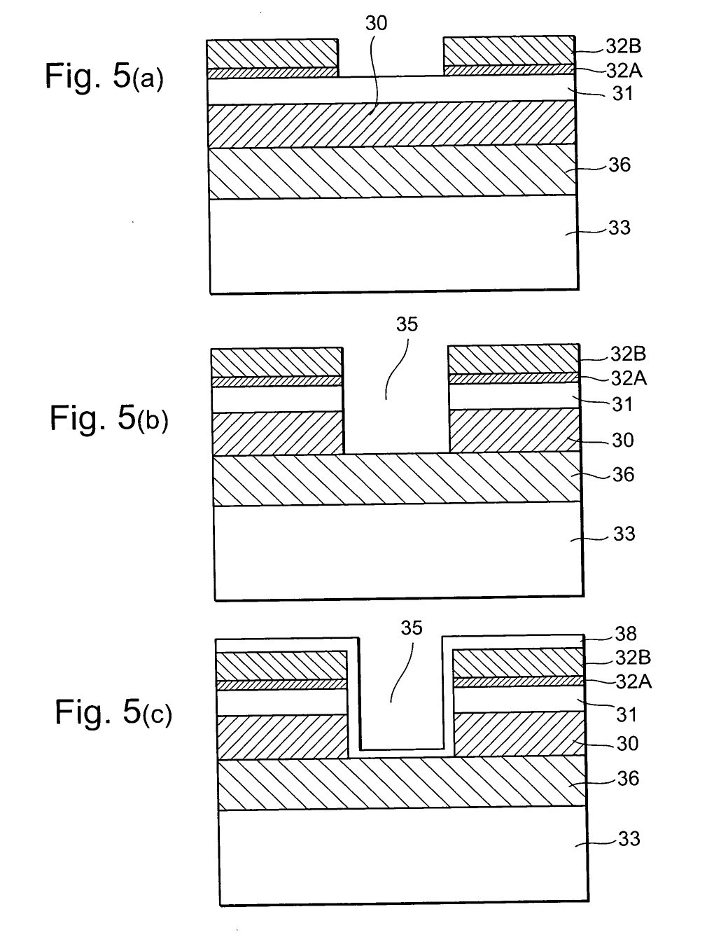

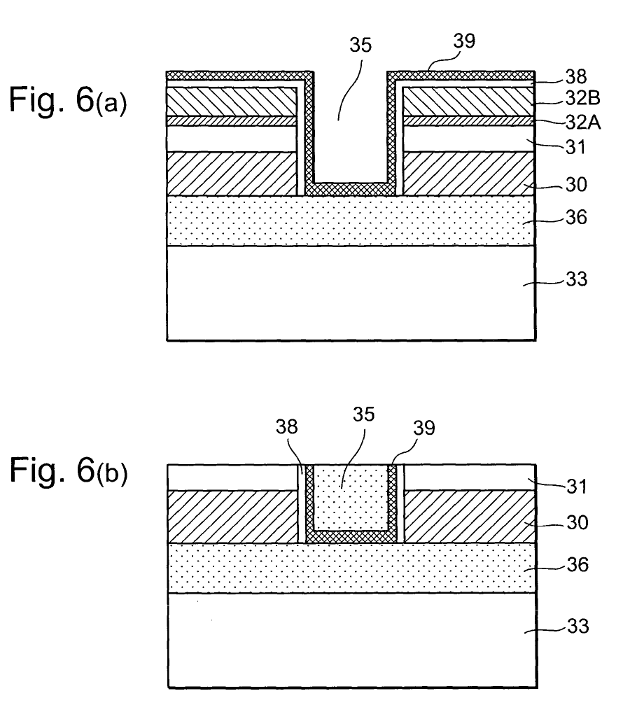

FIGS. 5 and 6 are sectional views for explaining a method of manufacturing element isolation structure in a semiconductor device according to a third embodiment of the invention. In this embodiment, for a substrate including element isolation structure, an SGOI substrate in which an SGOI layer 30 is formed on an Si substrate 33 via a buried oxide film 36 and a silicon thin film layer 31 is provided on the SGOI layer 30 is used.

First, as shown in FIG. 5(a), as in the first embodiment, after a pad oxide film 32A and a mask nitride film 32B are laminated on the silicon thin film layer 31, an opening is formed in a region of a trench. Next, as shown in FIG. 5(b), a trench 35 is formed in the silicon thin film layer 31 and the SGOI layer 30 using the mask nitride film 32B as a mask by dry etching, however, at this time, etching is performed until the bottom of the trench 35 reaches the buried oxide film 36. Next, as shown in FIG. 5(c), a silicon thin film 38 is formed overall, however, at this time, a condition for forming the silicon thin film 38 is selected so that the silicon thin film is epitaxially grown on the surfaces of the SGOI layer 30 and the silicon thin film 31 on the side of the trench and is amorphous on the buried oxide film 36 at the bottom of the trench.

Next, as shown in FIG. 6(a), the silicon thin film 38 is thermally oxidized, however, at this time, the silicon thin film 38 in an amorphous state at the bottom of the trench has a higher thermally oxidizing velocity than the silicon thin film 38 epitaxially grown on the side of the trench. Therefore, thermal oxidation time can be optimized according to the thickness of the silicon thin film 38 so that the silicon thin film 38 at the bottom almost all becomes a silicon oxide film and the silicon thin film 38 on the side becomes a silicon oxide film partially in a direction of the thickness. Next, as shown in FIG. 6(b), after an insulating film 37 is buried in the trench by the similar method to that in the first embodiment, films above the upper surface of the silicon thin film 31 are removed by CMP and wet etching.

It is clear that the element isolation structure in this embodiment produces the similar effect to the element isolation structure in the first embodiment. Furthermore, in this embodiment, as the SGOI substrate is used for a substrate, the individual active layer region in which the transistor is formed can be completely electrically isolated by the insulating film on the side and at the bottom. Besides, as thermal oxidation is performed after the trench is formed, a defect may be removed from the buried oxide film damaged by dry etching when the trench is produced of the SGOI substrate or the SOI substrate and hereby, the SOI device having higher performance can be provided.

For a substrate which can be used in this embodiment for forming element isolation structure, a structure in which the SGOI layer is formed on the Si substrate via the buried oxide film and the silicon thin film layer exists on the SGOI layer is used. However, this embodiment can be applied to any structure provided with a semiconductor layer having at least one layer including germanium as one component on the buried oxide film or the substrate having SOI layer. As in the first embodiment, a substrate in which a silicon-germanium mixed crystal layer is epitaxially grown on an SOI substrate can be also used.

### Fourth Embodiment

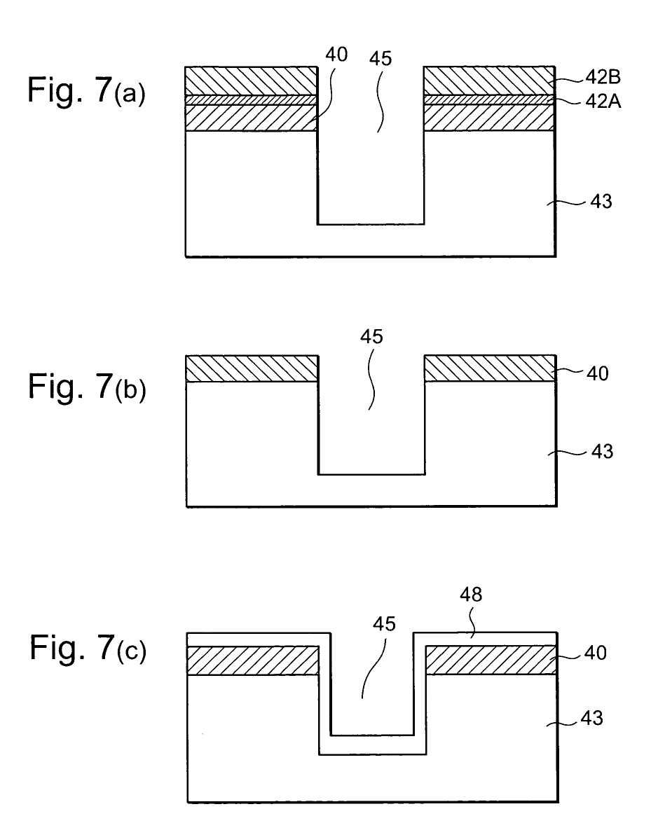

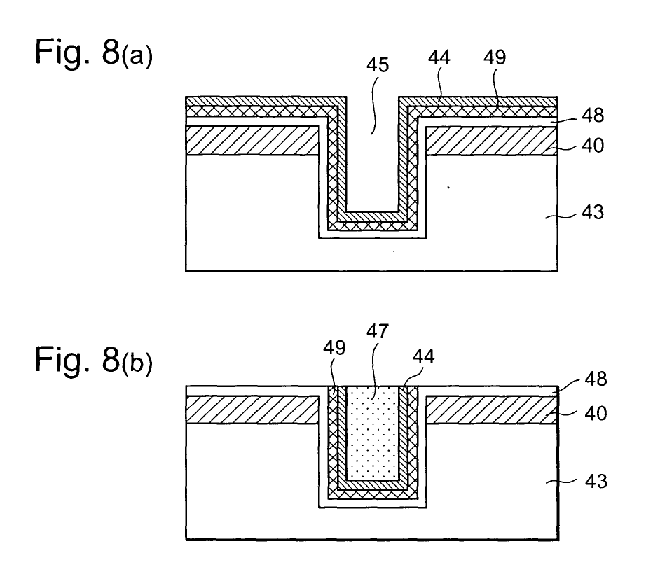

FIGS. 7 and 8 are sectional views for explaining a method of manufacturing isolation structure in a semiconductor device according to a fourth embodiment of the invention. In this embodiment, for a substrate, a substrate in which a silicon-germanium mixed crystal layer 40 is epitaxially grown on a silicon substrate 43 is used. The silicon-germanium mixed crystal layer 40 is the surface layer on the substrate.

First, as shown in FIG. 7(a), after a pad oxide film 42A and a mask nitride film 42B are laminated on the silicon-germanium mixed crystal layer 40 in the similar process to that in the first embodiment, a trench 45 that reaches the inside of the silicon substrate 43 is formed. It is preferable that the pad oxide film 42A is formed by CVD because the surface layer of the substrate in which the element isolation structure is produced is the silicon-germanium mixed crystal layer. Next, as shown in FIG. 7(b), the mask nitride film 42B and the pad oxide film 42A are removed by etching. Next, as shown in FIG. 7(c), when a silicon thin film 48 is epitaxially grown on the surfaces of the silicon substrate 43 and the silicon-germanium mixed crystal layer 40 on the side and at the bottom of the trench 45, the silicon thin film is also epitaxially grown in the following part because the silicon-germanium mixed crystal layer 40 is also exposed on the surface of the substrate in the part except the trench. Accordingly, the silicon thin film 48 is epitaxially grown overall.

Next, as shown in FIG. 8(a), after the silicon thin film 48 is partially thermally oxidized in a direction of the thickness and a silicon thermal oxide film 49 is formed, a silicon nitride film 44 is laminated. Afterward, as shown in FIG. 8(b), after an insulating film 47 made of a silicon oxide film is buried in the trench, the extra insulating film 47 over the trench is removed by CMP. CMP is stopped at a time when the silicon nitride film 44 is exposed, and thereafter, the silicon nitride film 44 and the silicon thermal oxidation film 49 except the trench are removed by wet etching.

In the isolation structure in this embodiment, the silicon nitride film 44 to be a cushioning layer exists between the silicon thermal oxide film 49 and the insulating film for isolating an element 47, and a similar effect to the element isolation structure in the second embodiment is produced. Besides, the silicon nitride film 44 also functions as a stopper layer in CMP.

Furthermore, in this embodiment, the silicon thin film 48 is epitaxially grown on the silicon-germanium mixed crystal layer 40 and if the strain of the silicon-germanium mixed crystal layer 40 is relaxed, the silicon thin film layer on the silicon-germanium mixed crystal layer is a distorted silicon layer. If a MOS transistor is formed according to a normal method of manufacturing a MOS transistor using the strained silicon layer for a channel after the element isolation structure is produced, a strained channel MOS transistor can be formed. As the silicon thin film layer to be a strained channel is epitaxially grown after the trench is formed, damage caused by dry etching in the silicon thin film layer to a strained channel can be prevented and defects caused by the relaxation of stress by the formation of the trench can be prevented. Furthermore, the silicon thin film layer to be a strained channel and the silicon thin film for isolating an element can be simultaneously formed and the number of processes for high-priced epitaxial growth can be reduced.

Also in this embodiment, as in the other embodiments, for a substrate for forming element isolation structure, a substrate having a germanium layer or a silicon-germanium mixed crystal layer into which carbon is doped in place of the silicon-germanium mixed crystal layer, an SGOI substrate and an SOI substrate on the surface of which a silicon-germanium mixed crystal layer or a germanium layer is epitaxially grown can be also used. The insulating film for isolating an element buried in the trench is not limited to the silicon oxide film and a substance having insulation performance such as a silicon oxynitride film and a silicon nitride film can be also used.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments without the use of inventive faculty. Therefore, the present invention is not intended to be limited to the embodiments described herein but is to be accorded the widest scope as defined by the limitations of the claims and equivalents.

What is claimed is:

1. A semiconductor device comprising:
a semiconductor substrate;
at least one isolation region buried insulating material in a trench formed in said semiconductor substrate;
a plurality of films in at least one part of a bounded area between said semiconductor substrate and said isolation region;
wherein said plurality of films comprises a silicon thin film and a silicon oxide film or a silicon oxynitride film, and
wherein said silicon thin film is nearer to said substrate than said silicon oxide film or said silicon oxynitride film.

2. The semiconductor device according to claim 1,
further comprising a silicon nitride film between said silicon oxide film or said silicon oxynitride film and said insulating material.

3. The semiconductor device according to claim 1,
wherein the semiconductor substrate comprises at least one germanium thin film layer or at least one semiconductor thin film layer including germanium in at least the vicinity of said isolation region from a surface of said semiconductor substrate to the bottom of the trench.

4. The semiconductor device according to claim 3,
wherein said semiconductor thin film layer including germanium is a silicon-germanium mixed crystal layer or a silicon-germanium mixed crystal layer doped carbon.

5. The semiconductor device according to claim 3,
wherein the semiconductor substrate comprises a plurality of germanium thin film layer or a semiconductor thin film layer including germanium.

6. The semiconductor device according to claim 3,
wherein said semiconductor substrate includes at least one other thin film layer or a part of the silicon substrate except said germanium thin film layer or said semiconductor thin film layer including germanium from the surface of said semiconductor substrate to the bottom of said trench.

7. The semiconductor device according to claim 6,
wherein the surface of said semiconductor substrate comprises a silicon thin film layer.

8. The semiconductor device according to claim 7,
wherein said silicon thin film layer of the semiconductor substrate and in the trench is continuously formed.

9. The semiconductor device according to claim 3,
wherein said semiconductor substrate comprises a silicon-germanium on insulator (SGOI) substrate.

10. The semiconductor device according to claim 9,
wherein the bottom of said trench reaches a buried oxide film of said SGOI substrate.

11. The semiconductor device according to claim 1,
wherein said insulating material comprises a silicon oxide film, a silicon oxynitride or a silicon nitride or is made of two or more materials thereof.

12. The semiconductor device according to claim 1,
wherein said semiconductor substrate comprises a silicon on insulator (SOI) substrate.

13. The semiconductor device according to claim 12,
wherein the bottom of said trench reaches a buried oxide film of said SOI substrate.

14. A semiconductor device comprising:
a semiconductor substrate;
at least one isolation region insulating material in a trench formed in said semiconductor substrate;
a plurality of films in at least one part of a bounded area between said semiconductor substrate and said isolation region;
wherein said semiconductor substrate comprises at least one germanium thin film layer or a semiconductor thin film layer including germanium in at least the vicinity of said isolation region from a surface of said semiconductor substrate to the bottom of the trench.

15. The semiconductor device according to claim 14,
wherein the nearest film of said plurality of films to said semiconductor substrate comprises silicon thin film.

16. A method of manufacturing a semiconductor device comprising:
forming at least one trench in a semiconductor substrate;
epitaxially growing a silicon thin film at the bottom and on the side of said trench;
partially thermally oxidizing or partially thermally oxynitriding said silicon thin film in a thickness direction in an oxidizing atmosphere or in an oxynitriding atmosphere and forming a silicon oxide film or a silicon oxynitride film on said silicon thin film; and
burying an insulating film for isolating an element in the trench.

17. The method of manufacturing a semiconductor device according to claim 16,
wherein said semiconductor substrate includes at least one germanium thin film layer or one semiconductor thin film layer including germanium.

18. The method of manufacturing a semiconductor device according to claim 17,
wherein a step of said forming a trench includes
forming a pad oxide film and a mask nitride film on said semiconductor substrate, and
patterning said pad oxide film and said mask nitride film in a pattern of said trench and exposing a part of the surface of the semiconductor substrate.

19. The method of manufacturing a semiconductor device according to claim 18,
wherein the surface layer of said semiconductor substrate is said germanium thin film layer or said semiconductor thin film layer including germanium; further comprising:
removing said pad oxide film and said mask nitride film by wet etching; and
epitaxially growing a silicon thin film at the bottom and on the side of said trench, and simultaneously epitaxially growing a silicon thin film layer on said surface layer of said semiconductor substrate.

20. The method of manufacturing a semiconductor device according to claim 16, further comprising:
forming a silicon nitride film on said silicon oxide film or said silicon oxynitride film between said steps of partially thermally oxidizing or partially thermally oxynitriding, and burying an insulating film.

21. The method of manufacturing a semiconductor device according to claim 16,
wherein said semiconductor substrate is a silicon germanium on insulator (SGOI) substrate or a silicon on insulator (SOI) substrate; and
forming said trench until the bottom of the trench reaches a buried oxide film of said SGOI substrate or said SOI substrate.
